(19) United States
(12) Patent Application Publication
(10) Pub. No.: US 2013/0235515 A1
(43) Pub. Date: Sep. 12, 2013

(54) ELECTRONIC DISPLAY INCLUDING AN OBSCURING LAYER AND METHOD OF MAKING SAME

(71) Applicants: Andrew J. Ouderkirk, St. Paul, MN (US); Scott B. Charles, Spring Valley, WI (US); Stanley C. Busman, North St. Paul, MN (US)

(72) Inventors: Andrew J. Ouderkirk, St. Paul, MN (US); Scott B. Charles, Spring Valley, WI (US); Stanley C. Busman, North St. Paul, MN (US)

(73) Assignee: 3M INNOVATIVE PROPERTIES COMPANY, St. Paul, MN (US)

(21) Appl. No.: 13/885,409

(22) PCT Filed: Nov. 2, 2011
(86) PCT No.: PCT/US2011/058872

§ 371 Date: May 15, 2013

Related U.S. Application Data
(60) Provisional application No. 61/416,022, filed on Nov. 22, 2010.

(51) Int. Cl. H05K 7/02; H05K 13/00

(52) U.S. Cl. CPC H05K 7/02; H05K 13/0023
USPC 361/679.01; 522/170; 522/182; 522/81; 523/400; 524/560; 156/275.5

(57) ABSTRACT

An electronic display (100) is provided that includes a display panel (106) having an image—forming region, a substantially clear photocured bonding layer (104) which is the reaction product of a first photocurable resin system disposed upon the image—forming region, an obscuring layer (108) in proximity to at least a portion of the substantially clear photocurable bonding layer, and a substantially transparent outer panel (106) in contact with at least a portion of the obscuring layer. The bonding layer (104) is disposed partially beneath the obscuring layer (108). The obscuring layer has an average light transmission of less than about 5% in the wavelength range of 420 nm to 700 nm and a light transmission of greater than about 5% in the wavelength range of 300 to 400 nm. Also provided is a method for making the electronic display.

### FIELD

This disclosure relates to electronic displays and methods of making the same.

### BACKGROUND

Electronic display panels often produce an image toward the center of the panel and have regions around at least one of the edges that are non-image producing. These dark edges can be useful for additional functions such as electrical connection, illumination with light sources, or bonding areas. When both the image and non-image areas of a display are covered with a transparent outer panel, for example a window or a touch panel, the dark edges can be masked from view with an obscuring layer. The obscuring layer can be made from a variety of materials such as a polymeric film, a deposited metal or inorganic material, or a printed ink. The obscuring layer can significantly block visible radiation from the edges of the display panel and can form a frame through which the image area of the display is viewed.

The outer panel may be bonded to the display panel using a light-curable adhesive, with the adhesive being exposed to light through the outer panel after the display panel and the outer panels have been assembled. The light-curable adhesive can include photocurable optically clear adhesive (OCAs) such as that disclosed, for example, in U.S. Pat. App. Publ. Nos. 2010/0086705 and 2010/0086706 (both Everaerts et al.). Light-curable adhesives used on optical displays typically cure by exposure to ultraviolet radiation (UV) so that they do not absorb any visible radiation and look transparent, color-neutral, and optically clear after curing.

The challenge in using a photocurable optically clear adhesive on a display panel that includes an obscuring layer is to get complete cure of the optically clear adhesive under the obscuring layer. The obscuring layer can present a problem, since the adhesive under the obscuring layer can have a much lower exposure to UV light, and may be only partially cured. The partially cured resin may increase the likelihood of the panel partially or completely delaminating, create the possibility of bubbles and other defects forming within the panel structure, and could potentially expose workers and users to uncured monomers and oligomers.

One method for curing an ultraviolet curable sealant that that is shadowed by metallization is disclosed in U.S. Pat. No. 6,284,087 (von Gutfeld et al.). This patent discloses the use of a light diffusion element positioned in the optical path of the UV radiation that causes a diffusion of the UV radiation so as to enable some of the diffused optical radiation to avoid the metallization features and to be incident on the sealant even in the areas directly blocked from the UV radiation.

### SUMMARY

Thus, there is a need for obscuring layers that can function as a dark edge on image-forming display devices. There is a need for obscuring layers to effectively block out most visible radiation from, for example, wavelengths of from about 420 nm to about 700 nm and yet allow enough UV radiation to penetrate through them to allow photocuring of a photocurable optically clear adhesive disposed beneath the obscuring layer. There is also a need for an ink having such properties than can be easily applied to the display panel, has the desired optical properties, and can allow curing of a photocurable optically clear adhesive disposed beneath.

In one aspect, an electronic display is provided that includes a display panel having an image-forming region, a substantially clear photocured bonding layer which is the reaction product of a first photocurable resin system disposed upon the image-forming region, an obscuring layer in proximity to at least a portion of the substantially clear first photocured bonding layer, and a substantially transparent outer panel in contact with at least a portion of the obscuring layer and at least a portion of the substantially clear first photocured bonding layer, wherein the obscuring layer has an average light transmission of less than about 5% in the wavelength range of 420 nm to 700 nm and UV transmission of greater than about 5% in the wavelength range of 300 to 400 nm. The image-forming region can be a part of a liquid crystal display device, a cathode-ray tube device, a light-emitting diode display device, or a combination thereof.

In another aspect, a resin system is provided that includes a substantially transparent photocurable resin system, at least one dye or pigment disposed in the substantially transparent resin system, and at least one photoinitiator disposed in the substantially transparent resin system, wherein the photocurable resin system has an average light transmission of less than about 5% in the wavelength range of 420 nm to 700 nm and an average UV transmission of greater than about 5% in the wavelength range of 300 to 400 nm. The substantially transparent resin system can include epoxy monomers, acrylic monomers, or a combination thereof.

In yet another aspect, a method of making an electronic display is provided that includes providing a display panel having an image-forming region, disposing a substantially clear photocurable bonding layer upon the image-forming region, covering the display panel with a substantially transparent outer panel that comprises an obscuring layer, wherein the obscuring at least partially covers the substantially clear cured bonding layer, and irradiating the substantially clear photocurable bonding layer through the substantially transparent outer panel, wherein the obscuring layer has an average light transmission of less than about 5% in the wavelength range of 420 nm to 700 nm and an average U V transmission of greater than about 5% in the wavelength range of 300 to 400 nm.

In this Disclosure:

“acrylate” refers to an ester of acrylic acid and, in this disclosure, also includes an ester of methacrylic acid;

“average visible transmission” refers to the average of the percent transmission of visible light measured at wavelengths of from 420 nm to 700 nm with a 1 nm resolution;

“average UV transmission” refers to the average of the percent transmission of visible light measured at wavelengths of from 300 nm to 400 nm with a 1 nm resolution;

“bonding layer” and “adhesive layer” are used interchangeably;

“cured” refers to a polymerizable system that has been exposed to a curing agent and has changed from liquid form to solid form by crosslinking or chain extension;

“photocurable” refers to a resin system that can harden upon exposure to light, usually in the ultraviolet region of the electromagnetic spectrum; and

“substantially transparent” refers to a system that has an average visible transmission of greater than about 90%

The provided electronic displays that include an obscuring layer can function as a dark edge on image-forming electronic display devices. The provided obscuring layers can effectively block out most visible radiation from about 420 nm to about 700 nm and yet allow enough UV radiation (300 nm to 400 nm) to penetrate through them to initiate photocuring of a photocurable optically clear adhesive disposed beneath the obscuring layer. An ink is also provided that can be easily applied to the edges of the electronic displays that can provide the properties outlined above.

The above summary is not intended to describe each disclosed embodiment of every implementation of the present invention. The brief description of the drawings and the detailed description which follows more particularly exemplify illustrative embodiments.

### BRIEF DESCRIPTION OF THE DRAWINGS

FIG. 1 is a cross-sectional view of a provided display.

FIG. 2 is a graph of the spectrum (UV and visible) of the obscuring layers of commercial electronic displays (prior art).

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

A display is provided that includes a display panel having an image-forming layer. In some embodiments, the display panel is a part of an electronic device. The electronic display can be any visible display of information that is a part of or in electronic communication with an electronic device. Examples of electronic display panels include flat panel displays that contain electroluminescent (EL) lamps, light-emitting diodes (LEDs), organic light-emitting diodes (OLEDs), or plasma components that create visible radiation—usually in a matrix display. Other examples of electronic display panels include reflective or backlit liquid crystal displays (LCD). Yet other examples of electronic display panels include reflective displays such as electrophoretic (EP) displays or electrowetting displays. The display panel has a viewable or image-forming region which may comprise the whole area of the display or some part of the display that can be viewed, for example, through an opening in a housing or through a frame. Generally, the image-forming region of an electronic display is that region which includes means for rendering changeable information in the form of images, figures, or text. In some embodiments, the image-forming region can also be touch-sensitive.

The provided display panel has a substantially clear cured bonding layer which is the reaction product of a first photocurable resin system disposed upon the image-forming layer. In some embodiments, the substantially clear photocured bonding layer includes an optically clear adhesive and laminates that include an optically clear adhesive. In some embodiments, the clear photocured bonding layer includes a pressure-sensitive adhesive and can, optionally, have antistatic properties. An adhesive or bonding layer can be considered to be optically clear if it exhibits an average optical transmission of at least about 80%, at least 90%, at least 95% or even higher of the light transmission in the range of 420 nm to 700 nm (visible light), and a haze value of below about 10%, or even lower, as measured on a 25 μm thick sample. Pressure-sensitive adhesives useful in the present invention include, for example, polyvinyl ethers, and poly(meth)acrylates (including both acrylates and methacrylates).

Any suitable adhesive composition can be used for provided display. In specific embodiments, the adhesive is pressure sensitive and optically-transmissive. Pressure sensitive adhesives (PSAs) are well known to possess properties such as aggressive and even permanent tack, adherence to a substrate with no more than finger pressure, sufficient ability to hold onto an adherend, and/or sufficient cohesive strength to be removed cleanly from the adherend. Furthermore, the pressure sensitive adhesive can be a single adhesive or a combination of two or more pressure sensitive adhesives.

In some embodiments, the photocured bonding layer is the reaction product of a first photocurable resin system made from acrylic precursors. These precursors can include acrylic oligomers, and monomers. Useful monomers include acrylic acid esters such as alkyl acrylates. Useful alkyl acrylates (i.e., acrylic acid alkyl ester monomers) include linear or branched monofunctional acrylates or methacrylates of non-tertiary alkyl alcohols, the alkyl groups of which have from 1 up to 14 and, in particular, from 1 up to 12 carbon atoms. Useful monomers include butyl(meth)acrylate, 2-ethylhexyl(meth)acrylate, ethyl(meth)acrylate, methyl(meth)acrylate, n-propyl(meth)acrylate, isopropyl(meth)acrylate, pentyl(meth)acrylate, n-octyl(meth)acrylate, isooctyl(meth)acrylate, isononyl(meth)acrylate and 2-methyl-butyl(meth)acrylate. In addition, small amounts of di- or multi-functional acrylates or acrylic acids (e.g., up to 5 weight percent) can be included as acrylic precursors.

In some embodiments, the pressure sensitive adhesive is based on at least one poly(meth)acrylate

(e.g., is a (meth)acrylic pressure sensitive adhesive). Poly(meth)acrylate pressure sensitive adhesives are derived from, for example, at least one alkyl(meth)acrylate ester monomer such as, for example, isooctyl acrylate (IOA), isononyl acrylate, 2-methyl-butyl acrylate, 2-ethyl-hexyl acrylate and n-butyl acrylate, isobutyl acrylate, hexyl acrylate, n-octyl acrylate, n-octyl methacrylate, n-nonyl acrylate, isoamyl acrylate, n-decyl acrylate, isodecyl acrylate, isodecyl methacrylate, and dodecyl acrylate; and at least one optional co-monomer component such as, for example, (meth)acrylic acid, N-vinyl pyrrolidone, N-vinylcaprolactam, N,N-dimethyl(meth)acrylamide, N-isopropyl(meth)acrylamide, (meth)acrylamide, isobornyl acrylate, 4-methyl-2-pentyl acrylate, a hydroxyalkyl(meth)acrylate, a vinyl ester, a polystyrene or polymethyl methacrylate macromer, alkyl maleates and alkyl fumarates (based, respectively, on maleic and fumaric acid), or combinations thereof.

In other embodiments, the poly(meth)acrylic pressure sensitive adhesive can be derived from a composition of between about 0 and about 4 weight percent (wt) of hydroxyalkyl(meth)acrylate and between about 100 wt % and about 96 wt % of at least one of isooctyl acrylate, 2-ethyl-hexyl acrylate or n-butyl acrylate. One specific embodiment can be derived from a composition of between about 1 wt % and about 2 wt % hydroxyalkyl(meth)acrylate and between about 99 wt % and about 98 wt % of at least one of isooctyl acrylate, 2-ethylhexyl acrylate or n-butyl acrylate. One specific embodiment can be derived from a composition of about 1 wt % to about 2 wt % hydroxyalkyl(meth)acrylate, and about 99 wt % to about 98 wt % of a combination of n-butyl acrylate and methyl acrylate.

In some embodiments, the photocured bonding layer can be a cloud point-resistant, optically clear adhesive composition. By cloud point-resistant it is meant that the adhesive composition, which is initially optically clear, remains optically clear after exposure to high temperature and humidity environments and subsequent cooling to ambient conditions. Optically clear adhesives are commonly used to mount optical films, such as polarizers or retardation plates, to display panels, such as liquid crystal cells in LCD applications. As such, the OCA is used to laminate the film to the display panel to form an optically clear laminate. When used in a laminate, a cloud point-resistant, optically clear adhesive allows the laminate to remain virtually haze free or clear after exposure to nonambient temperature and humidity conditions.

Cloud point-resistant adhesive compositions incorporate hydrophilic moieties into the OCA to obtain haze-free optical laminates that remain haze-free even after high temperature/humidity accelerated aging tests. In one aspect, the provided adhesive compositions are derived from precursors that include from about 75 to about 95 parts by weight of an alkyl acrylate having 1 to 14 carbons in the alkyl group. The alkyl acrylate can include aliphatic, cycloaliphatic, or aromatic alkyl groups. Useful alkyl acrylates (i.e., acrylic acid alkyl ester monomers) include linear or branched monofunctional acrylates or methacrylates of non-tertiary alkyl alcohols, the alkyl groups of which have from 1 up to 14 and, in particular, from 1 up to 12 carbon atoms. Useful monomers include, for example, 2-ethylhexyl(meth)acrylate, ethyl(meth)acrylate, methyl(meth)acrylate, n-propyl(meth)acrylate, isopropyl(meth)acrylate, pentyl(meth)acrylate, n-octyl(meth)acrylate, isooctyl(meth)acrylate, isononyl(meth)acrylate, n-butyl(meth)acrylate, isobutyl(meth)acrylate, hexyl(meth)acrylate, n-nonyl(meth)acrylate, isoamyl(meth)acrylate, n-decyl(meth)acrylate, isodecyl(meth)acrylate, dodecyl(meth)acrylate, isobornyl(meth)acrylate, cyclohexyl(meth)acrylate, phenyl meth(acrylate), benzyl meth(acrylate), and 2-methylbutyl(meth)acrylate, and combinations thereof.

Cloud point-resistant adhesive composition precursors can also include from about 0 to about 5 parts of a copolymerizable polar monomer such as acrylic monomer containing carboxylic acid, amide, urethane, or urea functional groups. Weak polar monomers like N-vinyl lactams may also be included. A useful N-vinyl lactam is N-vinylcaprolactam. In general, the polar monomer content in the adhesive can include less than about 5 parts by weight or even less than about 3 parts by weight of one or more polar monomers. Polar monomers that are only weakly polar may be incorporated at higher levels, for example 10 parts by weight or less. Useful carboxylic acids include acrylic acid and methacrylic acid. Useful amides include N-vinyl caprolactam, N-vinyl pyrrolidone, (meth)acrylamide, N-methyl(meth)acrylamide, N,N-dimethyl acrylamide, N,N-dimethyl meth(acrylamide), and N-octyl(meth)acrylamide.

Cloud-point resistant adhesive compositions can also include from about 1 to about 25 parts of a hydrophilic polymeric compound based upon 100 parts of the alkyl acrylate and the copolymerizable polar monomer. The hydrophilic polymeric compound typically has a average molecular weight (Mₙ) of greater than about 500, or greater than about 1000, or even higher. Suitable hydrophilic polymeric compounds include poly(ethylene oxide) segments, hydroxyl functionality, or a combination thereof. The combination of poly(ethylene oxide) and hydroxyl functionality in the polymer needs to be high enough to make the resulting polymer hydrophilic. By “hydrophilic” it is meant that the polymeric compound can incorporate at least 25 weight percent of water without phase separation. Typically, suitable hydrophilic polymeric compounds may contain poly(ethylene oxide) segments that include at least 10, at least 20, or even at least 30 ethylene oxide units. Alternatively, suitable hydrophilic polymeric compounds include at least 25 weight percent of oxygen in the form of ethylene glycol groups from poly(ethylene oxide) or hydroxyl functionality based upon the hydrocarbon content of the polymer. Useful hydrophilic polymer compounds may be copolymerizable or non-copolymerizable with the adhesive composition, as long as they remain miscible with the adhesive and yield an optically clear adhesive composition. Copolymerizable, hydrophilic polymer compounds include, for example, CD552, available from Sartomer Company, Exton, Pa., which is a monofunctional methoxylated polyethylene glycol (550) methacrylate, or SR9036, also available from Sartomer, that is an ethoxylated bisphenol A dimethacrylate that has 30 polymerized ethylene oxide groups between the bisphenol A moiety and each methacrylate group. Other examples include phenoxypolyethylene glycol acrylate available from Jarchem Industries Inc., Newark, N.J. Other examples of polymeric hydrophilic compounds include poly acrylamide, poly-N,N-dimethylacrylamide, and poly-N-vinylpyrrolidone.

In some embodiments, cloud-point resistant optically clear adhesive compositions useful in the provided displays can be derived from precursors that include from about 60 parts by weight to about 95 parts by weight of an alkyl acrylate having 1 to 14 carbons in the alkyl group and from about 0 parts by weight to about 5 parts by weight of a copolymerizable polar monomer. The alkyl acrylate and the copolymerizable polar monomer are described above. The precursors also include from about 5 parts by weight to about 50 parts by weight of a hydrophilic, hydroxyl functional monomeric compound based upon 100 parts of the alkyl acrylate and the copolymerizable polar monomer or monomers. The hydrophilic, hydroxyl functional monomeric compound typically has a hydroxyl equivalent weight of less than 400. The hydroxyl equivalent molecular weight is defined as the molecular weight of the monomeric compound divided by the number of hydroxyl groups in the monomeric compound. Useful monomers of this type include 2-hydroxyethyl acrylate and methacrylate, 3-hydroxypropyl acrylate and methacrylate, 4-hydroxybutyl acrylate and methacrylate, 2-hydroxyethylacrylamide, and N-hydroxypropylacrylamide. Additionally, hydroxy functional monomers based on glycols derived from ethylene oxide or propylene oxide can also be used. An example of this type of monomer includes a hydroxyl terminated polypropylene glycol acrylate, available as BISOMER PPA 6 from Cognis, Germany Diols and triols that have hydroxyl equivalent weights of less than 400 are also contemplated for the hydrophilic monomeric compound. Cloud-point resistant adhesives and laminates are disclosed, for example, in U.S. Pat. Appl. Publ. Nos. 2010/0086705 and 2010/0086706 (Everaerts et al.).

In some embodiments, the substantially clear photocured bonding layer which is the reaction product of a first photocurable resin system can include an antistatic optically-transmissive adhesive. The antistatic adhesives can include one or more static-dissipating agents. A static-dissipating agent operates by removing static charge or by preventing build up of such charge. Antistatic agents useful in the provided constructions include non-polymeric and polymeric organic salts. Non-polymeric salts have no repeat units. Generally, the static-dissipating agent comprises an amount less than about 10 wt % of the antistatic pressure sensitive adhesive and optionally an amount less than about 5 wt % of the antistatic PSA. In addition, the static-dissipating agent comprises an amount greater than about 0.5% of the antistatic PSA and optionally an amount greater than about 1.0 wt % of the antistatic PSA. Examples of useful antistatic optically clear pressure sensitive adhesives can be found, for example, in U.S. Pat. Appl. Nos. 2010/0028564 (Cheng et al.) and 2010/0136265 (Everaerts et al.).

The substantially-transparent bonding layer may be based on photo-initiated polymerizable monomers, oligomers, and mixtures. Suitable materials include acrylates, silicones, epoxides and combinations thereof. Suitable photoinitiators include for acrylates, Norrish Type I such as acyl phosphine oxides (i.e., BASF's DAROCUR TPO) and oxime esters (i.e., BASF's OXE-1), Norrish Type II such as benzophenone derivatives (i.e., Cytec's Additol BP) and thioxanthones (i.e., DAROCUR ITX), and onium salts (i.e., IRGACURE 250); for silicones, photohydrosilation catalysts (Boardman, L. D. Organometallics 11, 4192-4201 (1992); Fry, B. E. and Neckers, D. C. Macromolecules 29, 5306-5312 (1996)); and for epoxies, photoacid generators such as from organometallic salts disclosed in U.S. Pat. No. 5,554,664 (Lamanna et al.)

Other materials can be added to the first photocured resin system for special purposes, including, for example, oils, plasticizers, antioxidants, UV stabilizers, pigments, curing agents, polymer additives, thickening agents, dyes, chain transfer agents and other additives provided that they do not significantly reduce the optical clarity of the pressure sensitive adhesive. In some embodiments, the plasticizer is provided in an effective amount to facilitate salt dissociation and ion mobility for static dissipation properties in the adhesive; for example, in an amount greater than about 0.01 parts by weight (pbw) based on 100 pbw of acrylic adhesive, optionally an amount greater than about 0.10 pbw, and in some embodiments in an amount greater than about 1.0 pbw may be used. In some embodiments, the plasticizer may be provided in for example, an amount less than about 20 pbw and optionally an amount less than about 10 pbw. In certain embodiments, the plasticizer may facilitate salt dissociation and ion mobility in the adhesive. In some embodiments, the plasticizer is selected from acrylic soluble plasticizers, including phosphate esters, adipate esters, citrate esters, phthalate esters, phenyl ether terminated polyethylene oxide oligomers. In general, non-hydrophilic plasticizers are preferred. Non-hydrophilic plasticizers do not take up significant amounts of moisture from the atmosphere at high humidity and elevated temperatures.

In some embodiments, the pressure-sensitive adhesive components can be blended to form an optically clear mixture. One or more of the polymeric components can be independently crosslinked or crosslinked with a common cross-linker. Ultraviolet, or “UV”, initiators may be used to cross-link the pressure sensitive adhesive. Such UV initiators may include benzophenones and 4-acryloxybenzophenones. Particularly useful are initiators such as IRGACURE 651, available from Ciba Chemicals, Tarrytown, N.Y., which is 2,2-dimethoxy-2-phenylacetophenone. Typically, the crosslinker, if present, is added to the precursor mixtures in an amount of from about 0.05 parts by weight to about 5.00 parts by weight based upon the other constituents in the mixture. The initiators are typically added to the precursor mixtures in the amount of from 0.05 parts by weight to about 2 parts by weight. The precursor mixtures can be polymerized and/or cross-linked using actinic radiation or heat to form the adhesive composition.

The substantially transparent bonding layer may be cured using one or a combination of UV or visible light sources, including low or high pressure metal vapor discharge lamps, arc lamps, excimer lamps, fluorescent lamps, lasers, and LEDs. The lamps may be configured to produce a higher intensity of light in the obscured areas. For example, UV-emitting LEDs may be arranged to have a higher lamp density, or power, or both in the edge region of a display panel, and a relatively low lamp density or power in the center region of the display panel. This will provide a more constant level of cure across the entire area of the panel, and reduce the cost and energy.

The pressure sensitive adhesive can be inherently tacky. If desired, tackifiers can be added to a base material to form the pressure sensitive adhesive. Useful tackifiers include, for example, rosin ester resins, aromatic hydrocarbon resins, aliphatic hydrocarbon resins, and terpene resins. In general, light-colored tackifiers selected from hydrogenated rosin esters, terpenes, or aromatic hydrocarbon resins can be used.

The provided displays include an obscuring layer in proximity to at least a portion of the substantially clear first photocured bonding layer. The obscuring layer can be made from a material that has a single pass average transmission of visible light of no more than 5%, typically no more than 1% between 420 and 700 nm. Transmission can be measured using a photopic detector with an ideal light source over the range of 420 to 700 nm. The obscuring layer can have transmission of at least 5% for at least a portion of the spectrum below 420 nm.

Suitable materials for the obscuring layer can include thin silver coatings, including multilayer silver/non-metal coatings such as silver/indium tin oxide (ITO). The thickness of the silver and ITO can be tuned to transmit UV radiation, and to reflect visible light. The obscuring layer may include interference mirrors made from dielectric materials, including polymers, inorganic materials, and combinations thereof. An example of a suitable system includes a multilayer construction of physical vapor deposited titania and silica. Exemplary multilayer interference mirrors are available, for example, from Edmund Optics, Barrington, N.J. Design of interference mirrors that transmit one region of the spectrum, and reflect others is well known to those skilled in the art, and designs can be optimized by software tools such as TFCALC made by Software Spectra Inc, Portland, Oreg.

Other suitable materials or the obscuring layer include visible light absorbing and UV light-transmitting dyes and pigments. For example, U.S. Pat. No. 6,858,289 (Pong et al.) describes solar blind dyes such as UV-transparent nanoporous silica glass having pores that are substantially filled with a UV-transparent solvent which has been selected to dissolve the dye. The dye can be dispersed in polyvinyl alcohol or porous glass and has substantial transmission in the UV, and has strong absorption over a substantial portion of the visible spectrum. The UV-transparent dyes may be combined with other dyes and pigments to have broad absorption in the visible spectrum. The dye can include cyanine and dithioic dyes. Useful cyanine dyes include linear cyanine dyes and cyclic cyanine dyes. Cyclic cyanine dyes include dyes such as 2,7-dialkyl-3,6-diazacyclohepta-1,6-diene where alkyl can be methyl, ethyl, n-propyl, isopropyl, sec-butyl, tert-butyl, n-hexyl, and dodecyl. Because the cyanines have one less π-electron than chain atoms, the molecule is a positively charged ion and is accompanied by a negatively charged counterion. Useful counterions include ClO₄⁻ (perchlorate), fluoride, bromide, iodide, and chloride.

Another particularly useful class of solar blind dyes is dithioic dyes, such as those having the formula RCS₂⁻X⁺ wherein R is H or alkyl and X is a cation. When R is alkyl, it may be methyl, ethyl, n-propyl, isopropyl, tert-butyl, n-pentyl, octyl, dodecyl, and cyclohexyl. Typically, the alkyl group can be a methyl, ethyl, isopropyl or tertiary butyl group. The cation X suitable for use with dithioic dyes of this type include, for example, alkali metals such as Na⁺, K⁺, Li⁺, Cs⁺, and Rb⁺; tetraalkylammonium cations such as N(CH₃)₄⁺ and N(C₂H₅)₄⁺; heterocyclic cations, such as C₅H₁₀NH₂⁺ (piperidinium). However, Na⁺, N(C₂H₅)₄⁺ and C₅H₁₀NH₂⁺ (piperidinium) are typical cations. Variation of the cation primarily influences the chemical stability of the dye material. For example, sodium salts are typically more sensitive to oxidation than the corresponding tetraalkylammonium salts. The synthesis of dithioic acid salts is familiar to those practiced in the art of organic chemistry. For example, such a process is described in Kato et al., Z. Naturforsch, 33b, 976-77 (1978). Other methods of synthesizing such dyes are described in Paquer, Bull. Chem. Soc. Fr., 1439 (1975) and Jansons, Russ. Chem. Rev., 45, 1035 (1976). Viable synthetic options include the reduction of CS₂ by an alkyl Grignard or alkyl lithium reagent, thiolysis of precursors such as CF₃CN, or oxidative sulfurization of aromatic aldehydes.

Another useful pigment that effectively transmits UV light and filters visible light radiation is disclosed, for example, in U.S. Pat. No. 4,042,849 (Wachtel). The filter comprises magnesium phosphate doped with cobalt and nickel having a formula,

Mg_{3-x-y}CoₓNi_{y}(PO₄)₂, with x+y from 1 to 1.4 and x/y from 0.8 to 1.2. Other useful blue-violet ceramic pigments based upon Co and MgCo₂₋ₓMgₓP₂O₇ disphosphates have been disclosed by M. Llusar et al., European Ceramic Society, 30, 1887-1896 (2010) such as magnesium-doped cobalt phosphate-doped pigments.

Other suitable materials that effectively transmits UV radiation and filters visible light radiation are the dyes and pigments used in manufacturing either incandescent or fluorescent “black lights”. Fluorescent “black lights” emit a relatively large amount of light in the UV, and a relatively small amount of visible light. “Black lights” are made by using a source that emits light over the visible and ultraviolet spectrum, and applying a filter that preferentially absorbs visible light. “Wood's glass”, which transmits ultraviolet light and absorbs visible light, is a well-known material that is used with “black lights” Wood's glass can be ground and dispersed in a binder to produce a patternable coating. “Woods glass” typically includes nickel oxide in barium-sodium-silicate glass as the absorber.

The dyes and pigments used in the obscuring layer typically can have low scatter for UV light. This can be achieved by using components with a small particle size, typically less than 1 micron (μm), less than 0.5 μm, or even less than 0.1 μm. Scatter can also be reduced by reducing the difference in refractive index between pigment and dye particles and the refractive index of the binder in the hardened state. Typically, the dyes and pigments in the obscuring layer are held in a binder.

Suitable binders include polymers such as polyacrylics in solvents, photocurable monomers and oligomers, and thermally-cured monomers and oligomers. The binder should have good UV transmission in the range of interest. Photocured systems typically use initiators that either absorb light in a different spectral range than any UV absorbing component in the gap-filling adhesive; additionally, the photoinitiator may photobleach when exposed to UV light, allowing for deeper penetration and thick section curing.

The obscuring layer may contain dyes and pigments to modify appearance as viewed from the outside surface. Suitable dyes and pigments include titanium dioxide, carbon black, and black dyes or dye mixtures. The obscuring layer may be applied in multiple layers, with for example, a first coating containing a black dye mixture, and a second coating layer containing a UV transparent pigment or dye. The first coating will reduce visible light back-scattered from the second coating or scattered from adjacent layers. The first coating can also mute color from the UV transparent coating. The UV-visible single-pass average light transmission of the first coating is preferably between 10 and 50%, measured with an ideal source, and ideal detector over the spectral range of interest, using a collimated source and the detector on an integrating sphere to collect scattered light.

The provided obscuring layer can be applied to a substrate, the display panel, or the outer panel by, for example, screen printing, transfer printing, sublimation printing, foil stamping, and ink jetting. Different printing methods may be used for the first and second coating. The obscuring layer can include a photoinitiator and can be cured by exposure to radiation that is of a wavelength that can be absorbed by the photoinitiator, typically in the ultraviolet. Alternatively, the obscuring layer can include a thermal initiator and can be cured thermally after it is applied to the substantially transparent outer cover and before the cover is adhered to the display panel.

In some embodiments, the obscuring layer can include a multi-layer interference stack. Such multi-layer stacks can be assembled so that they have high transmission in the ultraviolet and low transmission in the visible part of the electromagnetic spectrum. These stacks are well known to those of ordinary skill in the art and can be made, for example, by alternating layers of a high index of refraction material such as titanium dioxide and a low index of refraction material such as silicon dioxide. Polymeric multi-layer optical interference filters are also contemplated in this application.

In some applications, the obscuring layer must have sufficient opacity to block ambient light from passing through the layer to underlying surfaces, and block light reflecting from these structures. Typically, there is less than about 5% light transmitted by the obscuring layer. In other applications, the obscuring layer must also block light emitted from the display panel, or other light sources such as LEDs for a backlight. In these cases it is the obscuring layer can have less than 2% transmission for the display light, or even less than 1% transmission.

Curing the adhesive through the provided obscuring layer may be accomplished by increasing the total UV exposure in the area covered by the obscuring layer relative to what is required in the more transparent image area. Attenuation of light by the obscuring layer increases the total UV fluence required; this can increase the cost of production through the use of higher power lamps, and may reduce throughput efficiency due to longer exposure time. In some cases, it will not be practical to cure the gap-filling adhesive under the obscuring layer. In general, it is preferred that the ratio of the curing light fluence for the obscured vs. unobscured area is less than 20:1. In some applications, it is desired that the obscured layer have very low reflectivity, and that the reflected light have a controlled, and in many applications, muted hue.

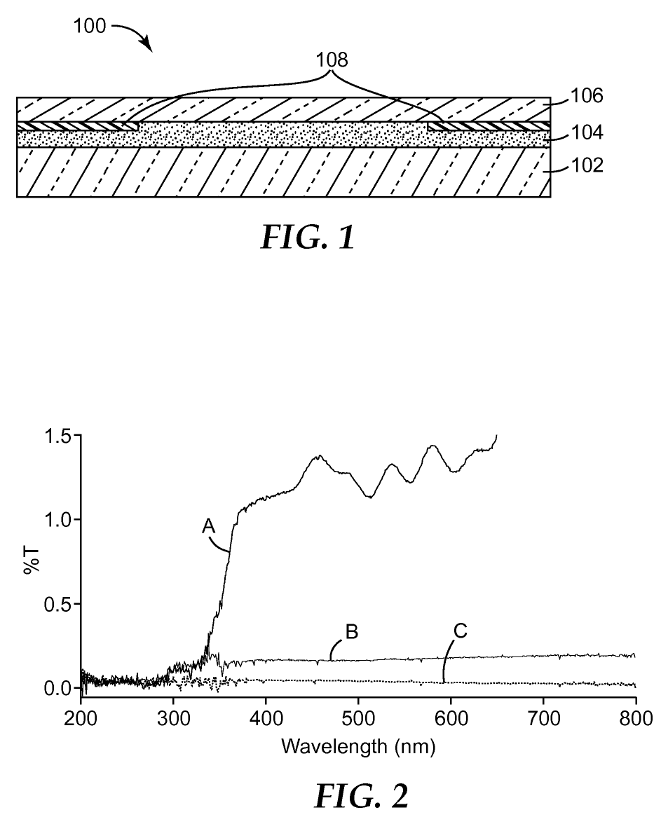

One embodiment of the provided display is illustrated in FIG. 1. FIG. 1 is a cross-sectional view of provided display 100. Display panel 102 is bonded to substantially transparent outer panel 106 with substantially clear photocured bonding layer 104. Obscuring layers 108 cover a portion of the panel area as viewed from the front. The function of the obscuring layer is partially aesthetic in covering areas that are not part of the display's image, including edge connectors, light sources, mounting devices, and the like. Typically, the obscuring area covers the peripheral area of the display panel assembly.

The outer panel may be made from transparent glass or polymers. The outer panel may include touch functions, and may have various coatings and layers. In this application, all coatings, layers, and transparent materials should have a combined effective transmissivity of at least 20% for at least a portion of the spectrum below 420 nm.

In another aspect, a method of making a display is provided that includes providing a display panel having an image-forming region. Display panels having an image-forming region are described above in this application. In the provided method, a substantially clear photocurable bonding layer is disposed upon the image-forming region also as described above. The display panel is then covered with a substantially transparent outer panel that comprises an obscuring layer. The obscuring layer at least partially covers the substantially clear photocurable bonding layer. The substantially clear photocurable bonding layer is then irradiated through the substantially transparent outer panel. The irradiation can be done at any wavelength that causes the photocurable bonding layer to react but is typically in the UV region of the spectrum between about 300 nm and 400 nm.

The obscuring layer can be applied to the underside of the substantially transparent outer panel before the display panel is covered. If the obscuring layer is a liquid such as a pigmented ink, the obscuring layer can be applied by painting, brushing, spraying, rolling, ink-jetting, screen printing or any other method of application known in the art of applying polymer layers or paint layers. The obscuring layer can then be cured by exposure to UV radiation if it contains a complementary photoinitiating system or by heat if it contains a heat-activated initiating system. Curing by exposure to electron beam without an added initiator is also within the scope of this disclosure.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows. All references cited in this disclosure are herein incorporated by reference in their entirety.

Following are exemplary embodiments of an electronic display including an obscuring layer and method of making same, according to aspects of the present invention.

Embodiment 1 is an electronic display comprising: a display panel having an image-forming region; a substantially clear photocured bonding layer which is the reaction product of a first photocurable resin system disposed upon the image-forming region; an obscuring layer in proximity to at least a portion of the substantially clear first photocurable bonding layer; and a substantially transparent outer panel in contact with at least a portion of the obscuring layer and at least a portion of the clear bonding layer, wherein the obscuring layer has an average light transmission of less than about 5% for every wavelength in the wavelength range of 420 nm to 700 nm and an average UV transmission of greater than about 5% in the wavelength range of 300 to 400 nm.

Embodiment 2 is an electronic display according to embodiment 1, wherein the image-forming region is part of a liquid crystal display device, a cathode-ray tube display device, a light-emitting diode display device, or a combination thereof.

Embodiment 3 is an electronic display according to embodiment 1, wherein the first photocurable resin system comprises a photoinitiator having an absorption band in the 200 nm to 400 nm wavelength range.

Embodiment 4 is an electronic display according to embodiment 3, wherein the first photocurable resin system comprises acrylates.

Embodiment 5 is an electronic display according to embodiment 1, wherein the obscuring layer comprises the reaction product of a second photocurable resin system.

Embodiment 6 is an electronic display according to embodiment 5, wherein the second photocurable resin system comprises at least one pigment or dye.

Embodiment 7 is an electronic display according to embodiment 6, wherein the second photocurable resin system comprises a nickel oxide or a magnesium-doped cobalt phosphate-doped pigment.

Embodiment 8 is an electronic display according to embodiment 1, wherein the obscuring layer comprises a multi-layer optical stack.

Embodiment 9 is a resin system comprising: a substantially transparent photocurable resin system; at least one dye or pigment disposed in the substantially transparent resin system; and at least one photoinitiator disposed in the substantially transparent photocurable resin system, wherein the photocurable resin system has an average light transmission of less than about 5% in the wavelength range of 420 nm to 700 nm and a light transmission of greater than about 5% for every wavelength in the wavelength range of 300 to 400 nm.

Embodiment 10 is a resin system according to embodiment 9, wherein the substantially transparent resin system comprises epoxy monomers, acrylic monomers, or a combination thereof.

Embodiment 11 is a resin system according to embodiment 10, wherein the at least one photoinitiator comprises a free-radical initiator, a cationic initiator or a combination thereof.

Embodiment 12 is a resin system according to embodiment 9, wherein the at least one dye or pigment comprises a nickel oxide or a magnesium-doped cobalt phosphate-doped pigment.

Embodiment 13 is the reaction product of the resin system according to embodiment 9.

Embodiment 14 is a method of making an electronic display comprising: providing a display panel having an image-forming region; disposing a substantially clear photocurable bonding layer upon the image-forming region; covering the display panel with a substantially transparent outer panel that comprises an obscuring layer, wherein the obscuring at least partially covers the substantially clear photocurable bonding layer; and irradiating the substantially clear photocurable bonding layer through the substantially transparent outer panel, wherein the obscuring layer has an average light transmission of less than about 5% for in the wavelength range of 420 nm to 700 nm and a light transmission of greater than about 5% in the wavelength range of 300 to 400 nm.

Embodiment 15 is a method of making an electronic display according to embodiment 14, further comprising curing the obscuring layer.

Embodiment 16 is a method of making an electronic display according to embodiment 15, wherein curing the obscuring layer is by exposure to ultraviolet radiation.

Embodiment 17 is a method of making an electronic display according to embodiment 14, wherein the image-forming region is part of a liquid crystal display device, a cathode-ray tube display device, a light-emitting diode display device, or a combination thereof.

Embodiment 18 is a method of making an electronic display according to embodiment 14, wherein the photocurable bonding layer is the reaction product of a first photocurable resin system disposed upon the image-forming region of the display panel.

Embodiment 19 is a method of making an electronic display according to embodiment 14, wherein the obscuring layer comprises at least one pigment or dye.

Embodiment 20 is a method of making an electronic display according to embodiment 19, wherein the pigment comprises a nickel oxide or a magnesium phosphate-doped pigment.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the mechanical, electro-mechanical, and electrical arts will readily appreciate that the present invention may be implemented in a very wide variety of embodiments. This application is intended to cover any adoptions or variations of the preferred embodiments discussed herein. Therefore, it is manifestly intended that this invention be limited only by the claims and the equivalents thereof.

What is claimed is:

1. An electronic display comprising:
a display panel having an image-forming region;
a substantially clear photocured bonding layer which is the reaction product of a first photocurable resin system disposed upon the image-forming region;
an obscuring layer in proximity to at least a portion of the substantially clear first photocurable bonding layer; and
a substantially transparent outer panel in contact with at least a portion of the obscuring layer and at least a portion of the clear bonding layer,
wherein the obscuring layer has an average light transmission of less than about 5% for every wavelength in the wavelength range of 420 nm to 700 nm and an average UV transmission of greater than about 5% in the wavelength range of 300 to 400 nm.

2. An electronic display according to claim 1, wherein the image-forming region is part of a liquid crystal display device, a cathode-ray tube display device, a light-emitting diode display device, or a combination thereof.

3. An electronic display according to claim 1, wherein the first photocurable resin system comprises a photoinitiator having an absorption band in the 200 nm to 400 nm wavelength range.

4. An electronic display according to claim 3, wherein the first photocurable resin system comprises acrylates.

5. An electronic display according to claim 1, wherein the obscuring layer comprises the reaction product of a second photocurable resin system.

6. An electronic display according to claim 5, wherein the second photocurable resin system comprises at least one pigment or dye.

7. An electronic display according to claim 6, wherein the second photocurable resin system comprises a nickel oxide or a magnesium-doped cobalt phosphate-doped pigment.

8. An electronic display according to claim 1, wherein the obscuring layer comprises a multi-layer optical stack.

9. A resin system comprising:
a substantially transparent photocurable resin system;
at least one dye or pigment disposed in the substantially transparent resin system; and
at least one photoinitiator disposed in the substantially transparent photocurable resin system, wherein the photocurable resin system has an average light transmission of less than about 5% in the wavelength range of 420 nm to 700 nm and a light transmission of greater than about 5% for every wavelength in the wavelength range of 300 to 400 nm.

10. A resin system according to claim 9, wherein the substantially transparent resin system comprises epoxy monomers, acrylic monomers, or a combination thereof.

11. A resin system according to claim 10, wherein the at least one photoinitiator comprises a free-radical initiator, a cationic initiator or a combination thereof.

12. A resin system according to claim 9, wherein the at least one dye or pigment comprises a nickel oxide or a magnesium-doped cobalt phosphate-doped pigment.

13. The reaction product of the resin system according to claim 9.

14. A method of making an electronic display comprising:
providing a display panel having an image-forming region;
disposing a substantially clear photocurable bonding layer upon the image-forming region;
covering the display panel with a substantially transparent outer panel that comprises an obscuring layer, wherein the obscuring at least partially covers the substantially clear photocurable bonding layer; and
irradiating the substantially clear photocurable bonding layer through the substantially transparent outer panel,
wherein the obscuring layer has an average light transmission of less than about 5% for in the wavelength range of 420 nm to 700 nm and a light transmission of greater than about 5% in the wavelength range of 300 to 400 nm.

15. A method of making an electronic display according to claim 14, further comprising curing the obscuring layer.

16. A method of making an electronic display according to claim 15, wherein curing the obscuring layer is by exposure to ultraviolet radiation.

17. A method of making an electronic display according to claim 14, wherein the image-forming region is part of a liquid crystal display device, a cathode-ray tube display device, a light-emitting diode display device, or a combination thereof.

18. A method of making an electronic display according to claim 14, wherein the photocurable bonding layer is the reaction product of a first photocurable resin system disposed upon the image-forming region of the display panel.

19. A method of making an electronic display according to claim 14, wherein the obscuring layer comprises at least one pigment or dye.

20. A method of making an electronic display according to claim 19, wherein the pigment comprises a nickel oxide or a magnesium phosphate-doped pigment.
